(19) United States
(12) Patent Application Publication
(10) Pub. No.: US 2010/0226079 A1
(43) Pub. Date: Sep. 9, 2010

(54) Metal plate member, information display apparatus and panel unit manufacturing method

(75) Inventor: Hideyuki Fujikawa, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/662,977

(22) Filed: May 13, 2010

Related U.S. Application Data
(63) Continuation of application No. PCT/JP2007/073100, filed on Nov. 29, 2007.

(51) Int. Cl. H05K 7/00; F16M 13/02; B23P 11/00

(52) U.S. Cl. 361/679.01; 248/222.14; 29/525.11

(57) ABSTRACT

A metal plate member is formed with a long opening to communicate with a screw hole of each kind of panels with the screw hole formed at a different position on each side, is screwed by the long opening and the screw hole to be fixed to each kind of panels, and includes folding pieces each formed with a through hole, processed to be folded to a overlapping position where the through hole overlaps the long opening, and corresponding to the kinds of panels. The through hole of one folding piece overlaps a portion of the long opening which portion communicates the screw hole formed on the side of a corresponding kind of panel, the one folding piece blocks a screw hole formed on a side in each of the other kinds of panels, and one of the folding pieces is folded to the overlapping position.

This is a continuation application of PCT/JP2007/073100, filed on Nov. 29, 2007.

### TECHNICAL FIELD

The present invention is related to a metal plate member which is screwed to a panel on whose side face a screw hole is formed, an information display apparatus provided with a display panel fixed by the metal plate member, and a panel manufacturing method of manufacturing a panel unit by screwing the metal plate member to a panel.

### BACKGROUND ART

In the field of personal computer, it is required to make size reduction and weight reduction of an apparatus and display screen expansion mutually compatible. In order to meet such requirements, there are performed such measures that a display device using a thin type and light weight LCD panel is applied, and an optical source, a control board and the like are arranged not on a side of a LCD (liquid crystal display) panel but on a rear side thereof so as to expand a display screen by a portion in which a space is reduced between a housing and the LCD panel. This LCD panel, a control board to control the LCD panel and the like may be easily damaged by a shock and the like, and normally, the LCD panel and the control board are held together to a metal plate member made of metal and the metal plate member is fixed to a main unit housing so that the strength is improved.

Incidentally, it is common, in manufacturers who manufacture personal computers, to purchase manufactured LCD panels from dedicated manufacturers to attach the LCD panels in electronic apparatuses, without manufacturing the LCD panels internally. In addition, there are cases in which LCD panels are obtained from plural manufacturers. Even for a same kind personal computer, LCD panels from different manufacturers may be mounted.

However, in recent years, large size LCD panels have been developed one after another. It is an actual state in which sizes of the LCD panels, positions of metal plate members to be attached to the LCD panels and the like are not standardized among plural manufacturers who manufacture the LCD panels. Therefore, even in LCD panels whose external sizes are same and are manufactured in manufacturers, positions of screw holes and the like are slightly different from one another among plural kinds of LCD panels manufactured by plural manufacturers respectively, and so a manufacturer who manufactures personal computers is required to prepare separately metal plate members or screws which are compatible with plural kinds of LCD panels, and thus, there is a problem in which a cost increase and the management of products are caused to be complicated.

Regarding this point, it is performed to form a long opening overlapping plural screw holes provided respectively in the plural kinds of LCD panels and to screw at precise positions using jigs and the like. In addition, the patent document 1 discusses a thermal relay in which a gang plate with a slit is moved so that components may be made in commonality.

Patent Document 1: Japanese Laid-open Patent Application JP H05-274986

However, a method of screwing using a jig requires labors and time and so leads to a cost increase. In addition, in attempting to use the technique discussed in the Patent Document 1, because a special metal plate member provided with a slit of separate member is required, it causes a cost increase, or positions of the slits need to be adjusted according to screw positions of LCD panels, there is a problem that assembling requires labors.

In view of the foregoing, there are provided a metal plate member, an information display apparatus and a panel unit manufacturing method in which screw positions are different from one another in which it is possible to make commonality of components among plural kinds of display panels whose positions are different from one another.

### DISCLOSURE OF THE INVENTION

A basic mode of the metal plate member to obtain the above-described object, includes:

a long opening that is formed therein to communicate with a screw hole of each kind of plural kinds of panels in each of which the screw hole is formed at a position different from one another on each side face, wherein

the metal plate member is screwed by using the long opening and the screw hole so as to be fixed to each of the plural kinds of panels, and

the metal plate member further includes plural folding pieces each of which is formed with a through hole, and is processed to be folded to a overlapping position where the through hole overlaps the long opening, and which correspond to the kinds of panels, the through hole of one folding piece overlaps a portion of the long opening which portion communicates the screw hole formed on the side face of a corresponding kind of panel, the one folding piece blocks a screw hole formed on a side face in each of the other kinds of panels, and one of the plural folding pieces is processed to be folded to the overlapping position.

According to the basic mode of the metal plate member, the folding piece is folded according to a kind of panel so that the long opening of the metal plate member and the through hole provided in the folding piece communicate with each other. Therefore, it is possible to provide commonality of metal plate members and screws among plural kinds of panels. In addition, according to the basic mode of the metal plate member, it is unnecessary to prepare a plate member and the like as a separate member different form the metal plate member. Therefore, it is possible to suppress a cost increase and also it is possible to readily adjust a position of screw only by folding the folding pieces according to a kind of panel.

For the basic mode, an applied mode is preferable that, at a position where one folding piece processed to be folded to the overlapping position, of the plural folding pieces, is exposed in a state of being folded, a mark corresponding to the one folding piece is marked.

According to the applied mode, the folding pieces are processed to be folded and then the mark corresponding to a folding piece is exposed on the surface. Therefore, it is possible to readily check to which panel among the plural kinds of panels the metal plate member is fixed.

For the above-described mode, a mode is preferable that the long opening is a long opening extending in a thickness direction of the panel, and the through hole of each of the plural the folding pieces is a long opening extending in a direction intersecting the direction in which the long opening extends.

Each through hole of the respective plural folding pieces is a long opening extending in a direction intersecting the long opening extending in the thickness direction of a panel so that an error of the folding accuracy of the folding pieces may be absorbed.

In addition, for the above-described basic mode, an applied mode is preferable that the panel is a display panel which includes a display screen to display information, and the metal plate member is fixed to the side face of the panel, and spreads in a rear face side of the display screen.

Display panels are often obtained from plural manufacturers and are mounted in an electronic apparatus and the like. According to this applied mode, even though screw positions are different from one another among plural kinds of display panels, it is possible to provide commonality of a metal plate member and also it is possible to suppress a cost increase.

In addition, a basic mode of the information display apparatus to obtain the above-described purpose, includes:

a first display panel that is formed with a screw hole on a side face, and includes a display screen to display information;

a metal plate member that includes a long opening which is formed therein to communicate with a screw hole of each kind of plural kinds of display panels in each of which the screw hole is formed at a position different from one another on each side face, and that is screwed by using the long opening and the screw hole so as to be fixed to each of the plural kinds of display panels; and

a main unit housing in which the display panel fixed to the metal plate member is housed, wherein

the metal plate member includes plural folding pieces each of which is formed with a through hole, and is processed to be folded to a overlapping position where the through hole overlaps the long opening, and which correspond to the kinds of display panels, the through hole of one folding piece overlaps a portion of the long opening which portion communicates the screw hole formed on the side face of a corresponding kind of display panel, the one folding piece blocks a screw hole formed on a side face in each of the other kinds of display panels, and one folding piece corresponding to the first display panel of the plural folding pieces is processed to be folded to the overlapping position so as to be screwed to the first display panel.

According to the basic mode of the information display apparatus, it is possible to provide commonality of the metal plate members among plural kinds of display panels while suppressing a cost increase.

Further, a basic mode of the panel unit manufacturing method to obtain the above-described purpose is, by screwing a first panel on whose side face a screw hole is formed, and a metal plate member in which a long opening which communicates a screw hole of each kind of panels of plural kinds of panels whose screw hole positions of screw holes formed on side faces positions are different from each other, by using the long opening and the screw holes, wherein

the metal plate member further includes plural folding pieces each of which is formed with a through hole, and is processed to be folded to a overlapping position where the through hole overlaps the long opening, and which correspond to the kinds of panels, the through hole of one folding piece overlaps a portion of the long opening which portion communicates the screw hole formed on the side face of a corresponding kind of panel, the one folding piece blocks a screw hole formed on a side face in each of the other kinds of panels, and

the panel unit manufacturing method includes:

folding-processing of performing folding-processing, at the overlapping position, one of the folding piece corresponding to the first panel of the plural folding pieces; and

screwing, by using a screw, to the first panel, the metal plate member in a folded state obtained through the folding-processing.

According to the basic mode of the panel manufacturing method, only by folding a folding piece according to a kind of panel, it is possible to readily adjust a position of screw hole of the panel and a position of screw hole of the metal plate member.

Further, for the above-described panel unit manufacturing method, an applied mode is preferable that, 7. The panel unit manufacturing method according to claim 6, the folding-processing is processing of folding-processing, at the overlapping position, a folding piece corresponding to the first panel of the plural folding pieces, and marking a mark according to the folding piece at a position where the folding piece to be folded is in the folded state.

According to the preferable metal plate screwing method, it is possible to mark a mark according to the folding piece without adding a new process.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is an external view of a personal computer of a first embodiment of an electronic apparatus.

FIG. 2 is a side view of the personal computer.

FIG. 3 is a rear view of the personal computer.

FIG. 4 is bottom view of the personal computer.

FIG. 5 is an internal configuration diagram of the personal computer.

FIG. 6 is a rear view of the personal computer from which an upper rear casing is removed.

FIG. 7 is an rear view of a metal plate member and a LCD panel which are removed from the upper rear casing.

FIG. 8 is a rear view of the metal plate member and the LCD panel which are attached to the upper rear casing.

FIG. 9 is a front view of the metal plate member and the LCD panel which are attached to the upper rear casing.

FIG. 10 is a side view of LCD panels which are manufactured in manufacturers different from each other.

FIG. 11 is a side view of the metal plate member.

FIG. 12 illustrates enlarged views around a vertically long opening of the metal plate member.

FIG. 13 is a diagram illustrating a first display panel to which the metal plate member is screwed.

FIG. 14 is a diagram illustrating a second display panel to which the metal plate member is screwed.

### BEST MODE FOR CARRYING OUT THE INVENTION

In the following, with reference to the drawings, exemplary embodiments of the above-described metal plate member, information display apparatus and panel unit manufacturing method will be explained.

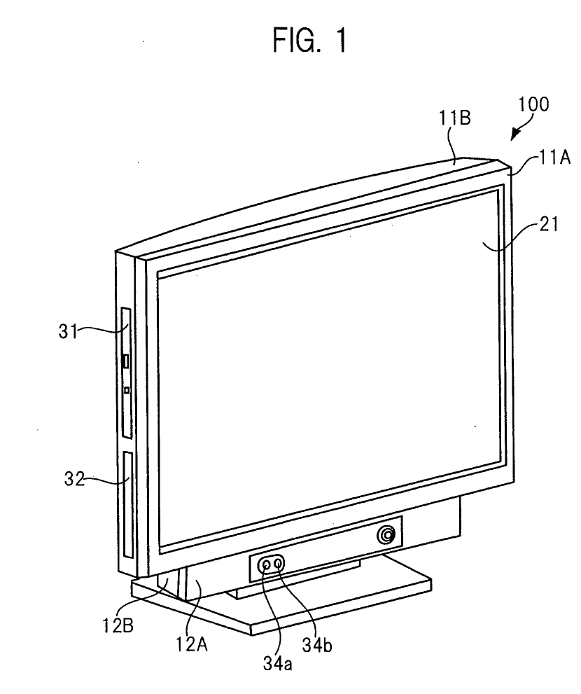

FIG. 1 is an external view of a personal computer 100 which is a first exemplary embodiment of the information display apparatus.

This personal computer 100 is an integrated main unit type personal computer in which a display device to display information is housed together with a hard disk device, a CPU and the like in a same housing. Incidentally, a keyboard, a mouse and the like, which are actually connected to the personal computer 100, are omitted to be illustrated in the drawing.

FIG. 1 illustrates a view of the personal computer 100 when viewed from front. The personal computer 100 houses a LCD panel in whose face a display screen 21 spreads, a CPU, a hard disk device, a cooling fan, a power supply device, various kinds of circuit boards and cables connecting them with each other in a space formed by an upper front casing 11A, an upper rear casing 11B, a lower front casing 12A and a lower rear casing 12B. The upper front casing 11A, the upper rear casing 11B, the lower front casing 12A and the lower rear casing 12B collectively correspond to an example of the main unit housing in the basic mode of the information display apparatus described above.

In addition, a start switch 34a to start the personal computer 100 and a display switch 34b to display information on a display screen 21 are provided in a front face of the personal computer 100. An optical disk loading opening 31 to load an optical disk such as a CD, a DVD and the like and a FD loading opening 32 to load a flexible disk (hereafter, referred to a FD) are provided on a side face of the personal computer 100.

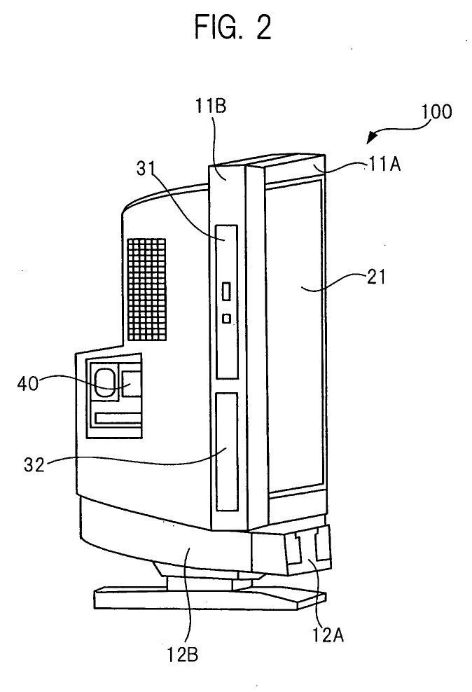

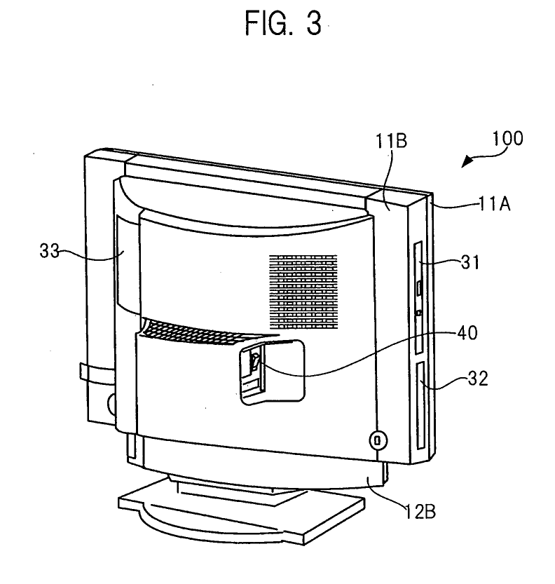

FIG. 2 is a side view of the personal computer 100, FIG. 3 is a rear view of the personal computer 100.

In the personal computer 100, the upper rear casing 11B is attached to the upper front casing 11A, and the lower rear casing 12B is attached to the lower front casing 12A. A LCD panel is engaged in the upper front casing 11A with the display screen 21 facing front. A hard disk device, various kinds of boards and the like are housed in a back face side of the display screen 21. The display screen 21 corresponds to an example of the display screen in the above described basic mode of the information display apparatus. In addition, a main power switch 40 to turn on power, and an extension card loading slot 33 to load an extension card for function extension such as a LAN card are provided in a back face of the personal computer 100.

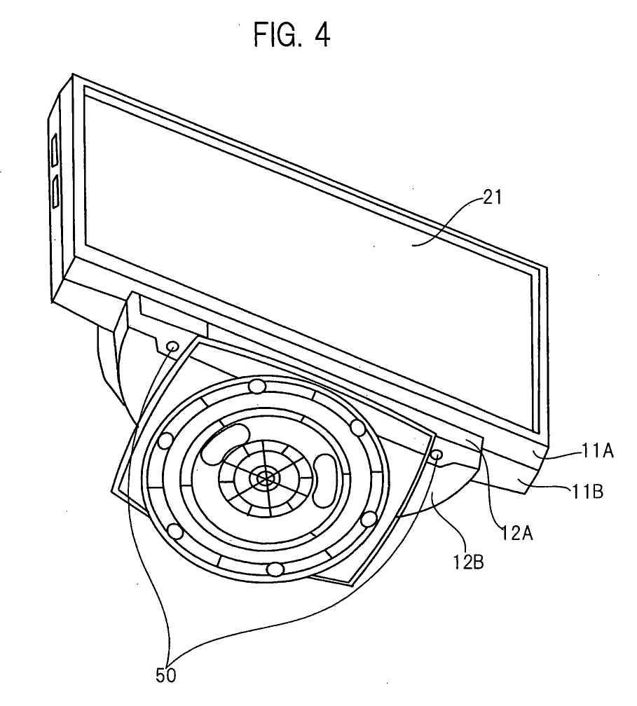

FIG. 4 is a bottom view of the personal computer 100.

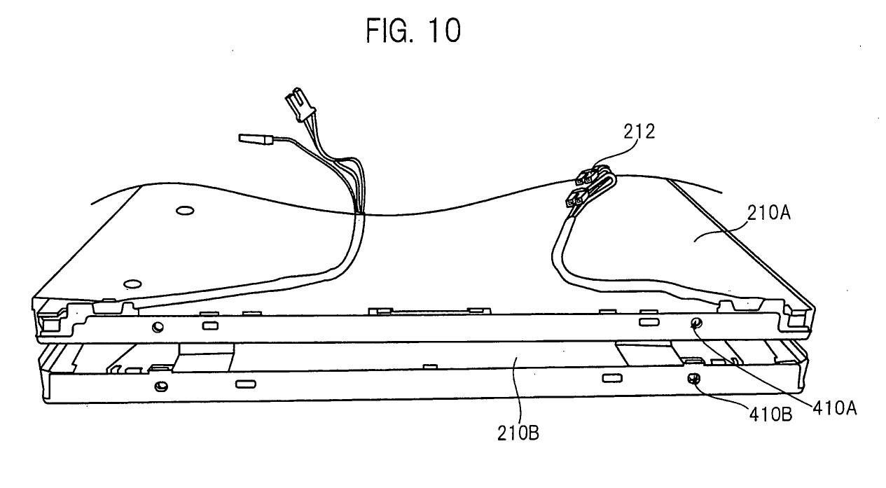

A changeable hard disk device and the like are housed in an upper part inside the personal computer 100. A board which is usually not changed and the like are housed to be protected in a housing frame in a lower part inside the personal computer 100. For example, the lower front casing 12A is a changeable plastic cover, a printed circuit board is attached to the housing frame made of metal (see FIG. 10), and the housing frame is fixed to the lower front casing 12A with screws 50.

In an ordinary repair, only the upper rear casing 11B is removed from the upper front casing 11A and changing the hard disk device housed in the upper part inside the personal computer 100 and the like are performed.

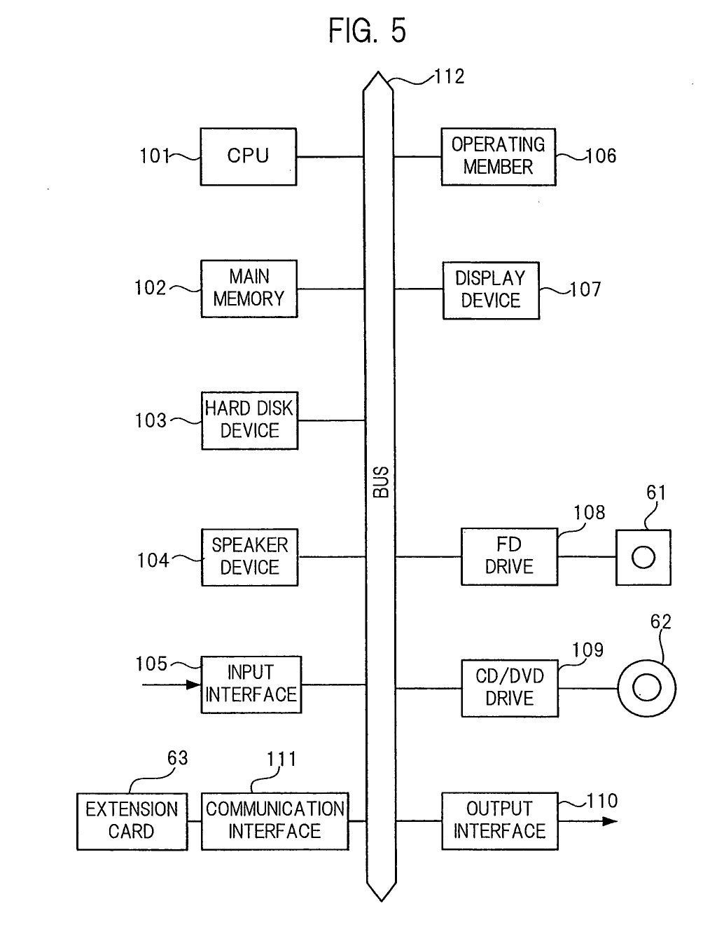

FIG. 5 is an internal schematic diagram of the personal computer 100.

As illustrated in FIG. 5, the personal computer 100 houses: a CPU 101 to execute various programs; a main memory 102 to which a program stored in a hard disk device 103 is read and expanded to be executed; the hard disk device 103 in which various kinds of programs, data and the like are stored; a speaker device 104 to generate a sound signal to be outputted; an input interface 105 to input data from an external device; operators 106 including a keyboard, a track pad and the like; a display device 107 to display information on the display screen 21, a FD drive 108 to which a FD 61 is loaded and which accesses the loaded FD 61, a CD/DVD drive 109 to which a CD-ROM 62 or a DVD is loaded and which accesses the loaded CD-ROM 62 or DVD, an output interface 110 to output data to an external device, a communication interface 111 to perform communication using an extension card 63. These elements are connected with each other through a bus 112.

Here, one of plural kinds of LCD panels obtained from plural manufacturers is mounted in the personal computer 100. A metal plate member made of metal is fixed to the LCD panel in order to improve the strength. Position shift of respective screw holes of the plural kinds of LCD panels is absorbed by the metal plate member. In the following, a panel unit manufacturing method of manufacturing a panel unit by screwing an LCD panel and the metal plate member with screw will be explained in detail.

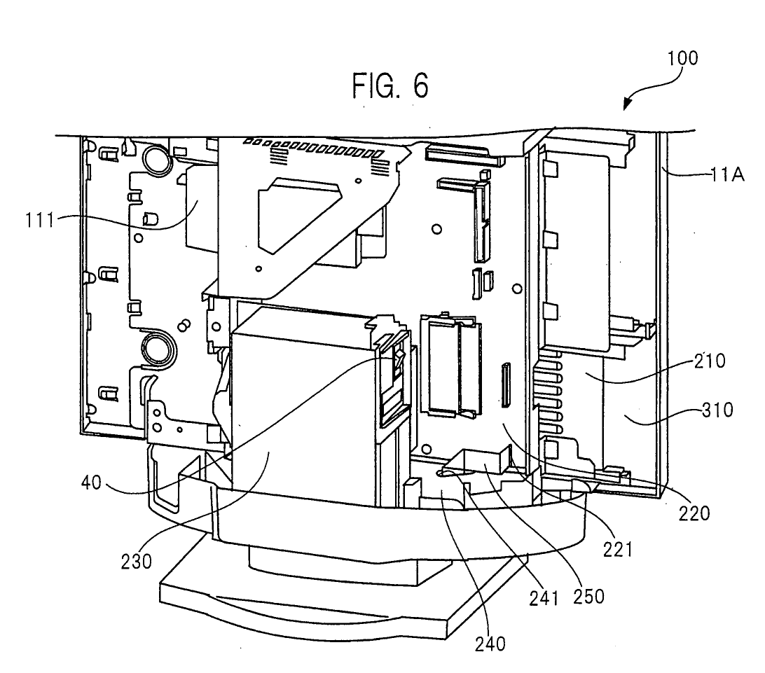

FIG. 6 is a rear view of the personal computer 100 from which the upper rear casing 11B is removed.

As illustrated in FIG. 6, the LCD panel 210 is held by the metal plate member 310 made of metal. The metal plate member 310 is fixed to the upper front casing 11A with the display screen 21 of the LCD panel 210 facing front. The LCD panel 210 corresponds to an example of the panel in the above-descried basic mode, and also corresponds to an example of the display panel in the above-described applied mode. In addition, the metal plate member 310 corresponds to an example of the metal plate member in the above-described basic mode.

The communication interface 111 illustrated also in FIG. 5, a main board 220 on which the hard disk device 103 and the like are mounted, the power supply device 230 to control electrical power and the like are overlappingly arranged on the rear face side of the LCD panel 210. The personal computer 100 is partitioned to an upper part and a lower part by a partition frame 240 which is a part of the housing frame. A printed circuit board on which the speaker device 104 (see FIG. 5), the various kinds of switches 33a, 34b (see FIG. 1) and the like are mounted is housed under the partition frame 240. In addition, the main board 220 and the printed circuit board are connected by a flat cable 250. A terminal on one end of the flat cable 250 is attached to a connector 221 of the main board 220. A terminal on another end of the flat cable 250 is attached through the through hole 241 to the printed circuit board.

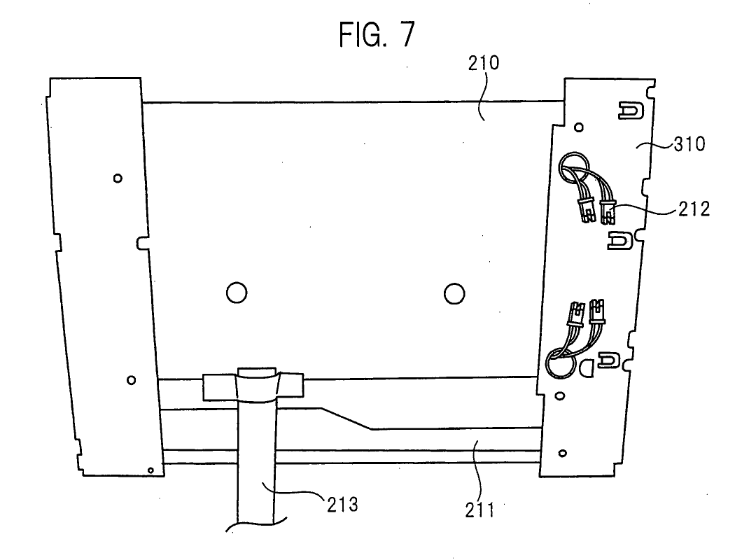

FIG. 7 is a rear view of the metal plate member 310 and the LCD panel 210 in a state of being removed from the upper rear casing 11B.

As illustrated in FIG. 7, the control board 211 to control the LCD panel 210 is folded to be overlaid in the rear face side of the LCD panel 210. The metal plate member 310 is fixed to both ends of the LCD panel 210 and the control board 211. The metal plate member 310 is provided with a wiring opening 311 through which a cable 212 extending from the LCD panel 210 passes. The cable 212 passing through the wiring opening 311 to the rear face side of the metal plate member 310 and the flat cable 213 extending from the control board 211 are connected to a printed circuit board hidden under the partition frame 240 of FIG. 6, and the like.

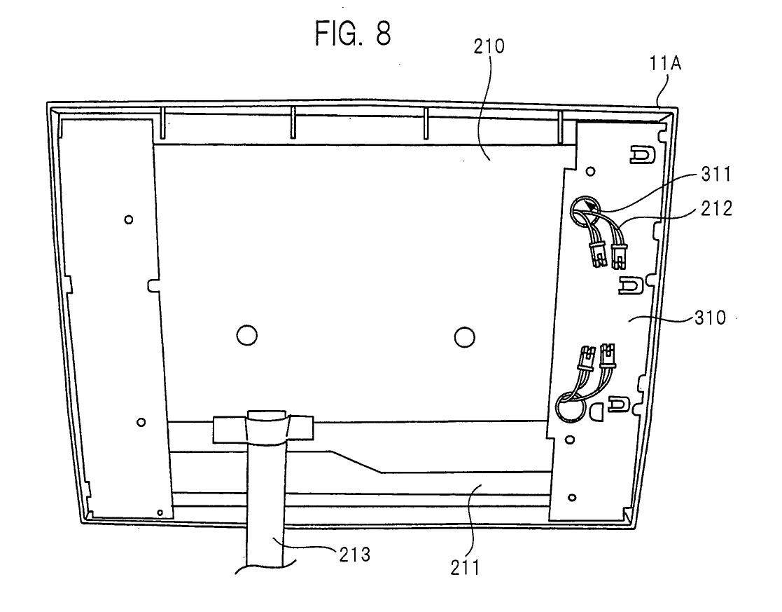

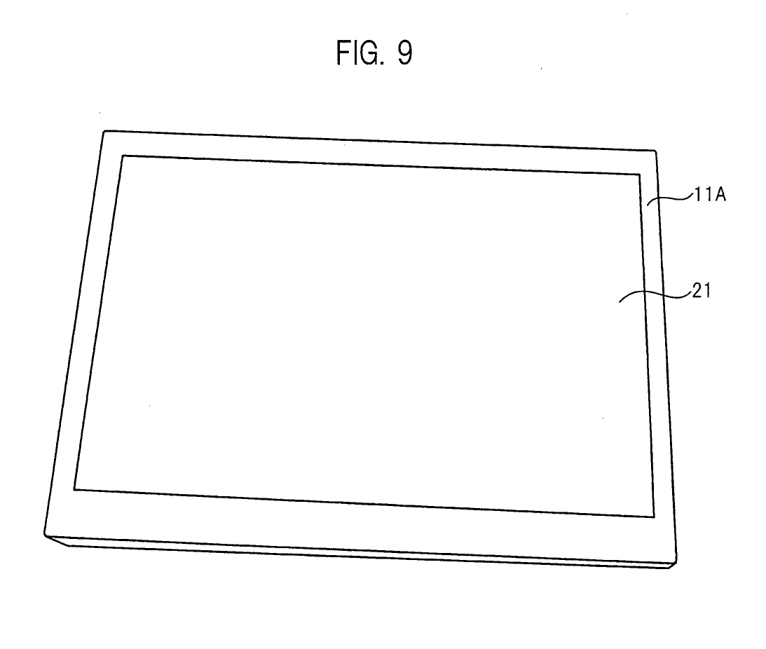

FIG. 8 is a rear view of the metal plate member 310 and the LCD panel 210 in a state of being attached to the upper rear casing 11B. FIG. 9 is a front view of the metal plate member 310 and the LCD panel 210 in a state of being attached to the upper rear casing 11B.

As illustrated in FIG. 8, the metal plate member 310 is fixed by holding the both ends of the LCD panel 210 and the control board 211. In addition, the metal plate member 310 is engaged in the upper rear casing 11B. Further, as described in FIG. 9, when viewed from the front face side where the display screen 21 is provided, the metal plate member 310 is hidden by the upper rear casing 11B.

Incidentally, as described above, the LCD panel 210 is obtained from plural manufacturers. The metal plate member 310, screws and the like which are common among those plural kinds of LCD panels 210 are used.

FIG. 10 is a side view of LCD panels manufactured by manufacturers different from each other.

Screw holes 410A, 410B with which the metal plate member 310 illustrated in FIG. 8 is screwed are provided on respective side faces of the LCD panels 210A, 210B illustrated in FIG. 10. Positions of those screw holes 410A, 410B are shifted from each other. The screw holes 410A, 410B correspond to an example of the screw hole in the above described basic embodiment.

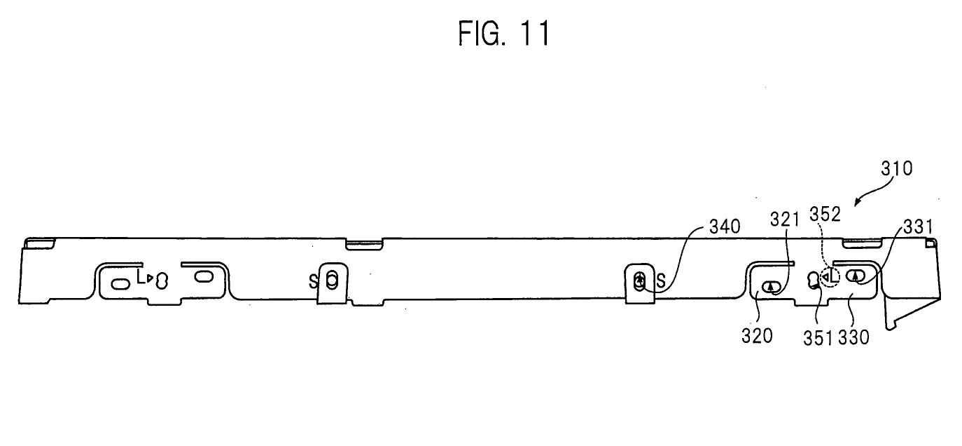

FIG. 11 is a side view of the metal plate member 310.

A vertically long opening 351 in which portions of respective two circular openings each corresponding to the screw holes 410A, 410B respectively of the LCD panels 210A, 210B illustrated in FIG. 10 overlap, two folding pieces 320, 330 capable of being folded from right and from left respectively toward the vertically long opening 351 and a through hole 340 for an auxiliary are provided on a side face of the metal plate member 310. In addition, a horizontally long opening 321 which overlaps with a lower side circular opening of the 351 when the folding piece 320 is folded is provided for one of the folding pieces 320. A horizontally long opening 331 which overlaps an upper side circular opening of the vertically long openings 351 when the folding piece 330 is folded is provided for another folding piece 330.

Incidentally, a mark 352 indicating that the two folding pieces 320, 330 are open is designated on a side of the vertically long opening 351. The vertically long opening 351 corresponds to an example of the long opening in the above-described basic mode. The two folding pieces 320, 330 correspond to an example of the plurality of folding pieces in the above described basic mode. In addition, the horizontally long openings 321, 331 correspond to an example of the through hole in the above-described basic mode and also correspond to an example of “the long opening extending in a direction intersecting a direction in which the long opening extends.”

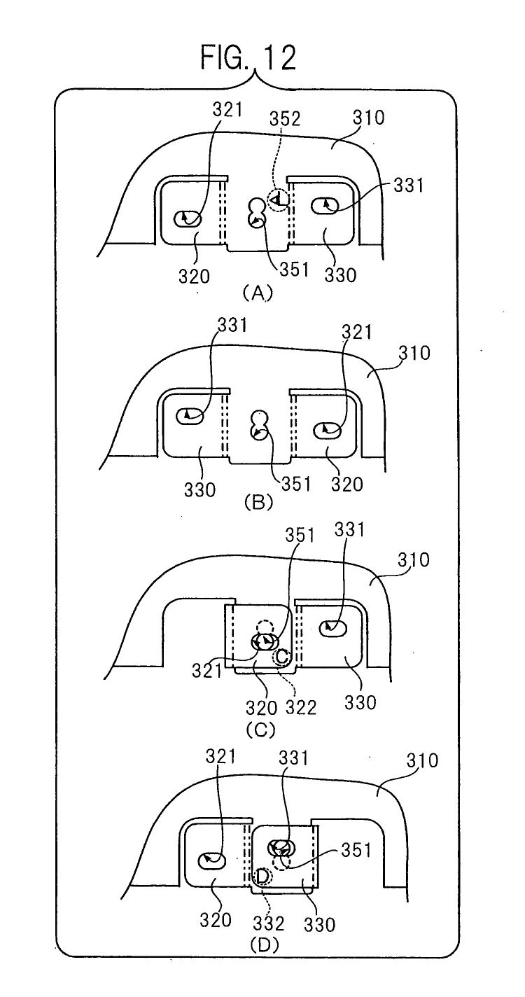

FIG. 12 illustrates enlarged views around the vertically long opening 351 of the metal plate member 310.

Part (A) of FIG. 12 illustrates a surface of the metal plate member 310 in a state before the two folding pieces 320, 330 are folded. In this state, the mark 352 indicating that the folding pieces are open is exposed on the surface.

Part (B) of FIG. 12 illustrates a rear face of the metal plate member 310 in a state before the two folding pieces 320, 330 are folded. In the state before the folding pieces 320, 330 are folded, there is no mark appeared in the rear surface of the metal plate member 310.

Part (C) of FIG. 12 illustrates a surface of the metal plate member 310 in a state where one of the two folding pieces 320, 330 is folded. When the folding piece 320 is processed to be folded, the horizontally long opening 321 of the folding piece 320 overlaps with the lower side circular opening of the two circular openings of the vertically long opening 351, and at the same time the upper side circular opening of the two circular openings is hidden. In addition, a mark 322 indicating that the folding piece 320 is bent is inscribed at a position where the folding piece 320 is exposed when bent. The mark 322 corresponds to an example of the mark in the above described applied mode.

Part (D) of FIG. 12 illustrates a surface of the metal plate member 310 in a state where another folding piece 330 different from the folding piece which is folded in part (C) of FIG. 12 of the two folding pieces 320, 330 is folded. When the folding piece 330 is processed to be folded, the horizontally long opening 331 of the folding piece 330 overlaps with the upper side circular opening of the two circular openings of the vertically long opening 351, and at the same time, the under side circular opening of the two circular openings is hidden. In addition, a mark 332 indicating that the folding piece 330 is bent is inscribed at a position where the folding piece 330 is exposed when bent. The mark 332 corresponds to an example of the mark in the above described applied mode.

Here, in the present embodiment, one of the two display panels 210A, 210B illustrated in FIG. 10 is mounted in the personal computer 100. The position of the screw hole 410A of the display panel 210A illustrated on the upper side of FIG. 10 of the two display panels 210A, 210B is shifted to an upper side, and the position of the screw hole 410B of the display panel 210B illustrated on the lower side of FIG. 10 of the two display panels 210A, 210B is shifted to a lower side.

The upper side circular opening of the vertically long opening 351 illustrated FIG. 12 and the horizontally long opening 321 of one of the folding piece 320 are provided at a position where the screw hole overlaps with the screw hole 410A of the first display panel 210A whose screw position is shifted to the upper side. In addition, the lower side circular opening of the vertically long opening 351 illustrated in FIG. 12 and the horizontally long opening 331 of the another folding piece 330 are provided at a position where the screw hole overlaps with the screw hole 410B of the display panel 210B whose screw position is shifted to the lower side.

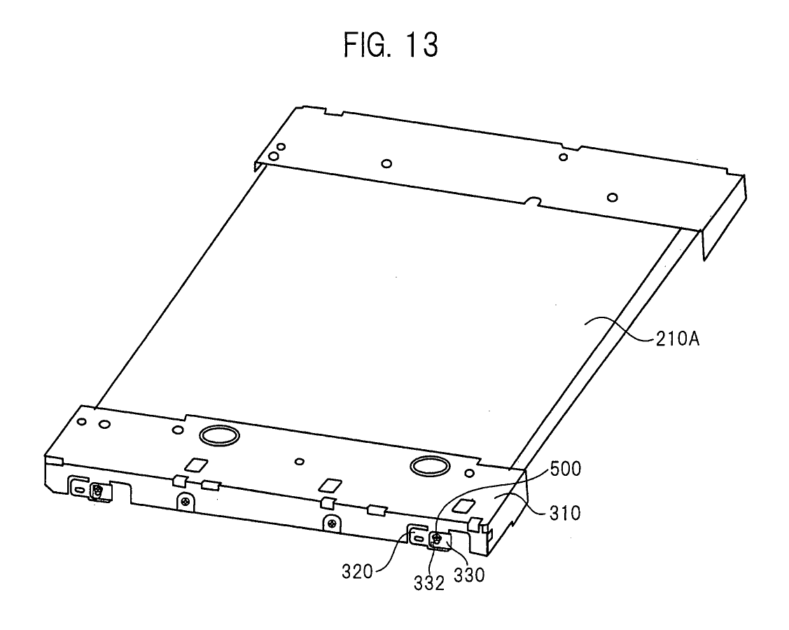

FIG. 13 is a diagram illustrating the first display panel 210A to which the metal plate member 310 is screwed.

When the first display panel 210A is mounted, the folding piece 320 which is provided with the horizontally long opening 321 at the position shifted to the lower side is folded, the mark 322 indicating that the folding piece is folded is inscribed. A process of folding the folding piece 320 corresponds to an example of the folding-processing in the basic mode of the above-described panel unit manufacturing method.

When the folding pieces 320 is folded, as illustrated in part (D) of FIG. 12, the upper side circular opening of the vertically long openings 351 overlaps with the horizontally long opening 321 of the folding piece 320, and in addition, the lower side circular opening of the vertically long openings 351 is closed. In this present embodiment, the horizontally long opening 321 extending in a direction intersecting a direction in which the vertically long opening 351 extends is provided in the folding piece 320. Therefore, an error according to a folding accuracy of the folding piece 320 is absorbed so that the vertically long opening 351 and the horizontally long opening may be securely communicated. Subsequently, a screw 500 is inserted into the vertically long opening 351, the horizontally long opening 321 and the screw hole 410A of the display panel 210A and then the metal plate member 310 is fixed to the display panel 210A. The process of screwing the metal plate member 310 to the display panel 210A corresponds to an example of the screwing in the above described basic mode of the panel unit manufacturing method.

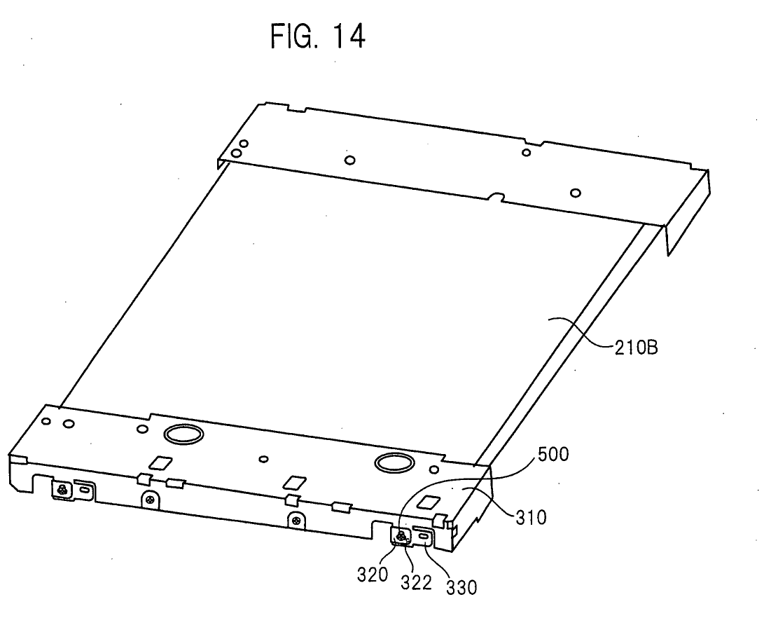

FIG. 14 is a diagram illustrating the second display panel 210A to which the metal plate member 310 is screwed.

When the second display panel 210B is mounted, the folding piece 330 in which the horizontally long opening 331 is provided at a position shifted toward the upper side is folded, a mark 332 indicating that the folding piece 330 is processed to be folded. The process of folding the folding piece 330 also corresponds to an example of the folding-processing in the above described basic mode of the panel unit manufacturing method.

When the folding piece 330 is folded, as illustrated in part (C) of FIG. 12, the lower side circular opening of the vertically long opening 351 overlaps with the horizontally long opening of the folding piece 330, and the screw 500 is inserted to the vertically long opening 351, the horizontally long opening 331 and the screw hole 410B of the display panel 210B so that the metal plate member 310 is fixed to the display panel 210B. The process of screwing the metal plate member 310 to the display panel 210B also corresponds to an example of the screwing in the above described basic mode of the panel manufacturing method.

As illustrated in FIG. 10, the positions of the screw holes 410A, 410B in the two display panels 210A, 210B are different from each other. The folding pieces 320, 330 corresponding respectively to those display panels 210A, 210B are folded so that the positions of the screws holes of the metal plate member 310 may be readily adjusted to positions matching the screw holes 410A, 410B of the display panels 210A, 210B. In addition, the folding pieces 320, 330 are folded so that one of the two circular openings included in the vertically long opening 351, which does not match the screw holes 410A, 4108 of the display panels 210A, 2108, is hidden. Therefore, it is possible to prevent a failure that the screw 500 is inserted into a wrong position. Further, when the two folding pieces 320, 330 are folded, the marks 322, 332 respectively corresponding to the bent folding pieces 320, 330 are exposed on the surface, and at the same time, the mark 352 marked on the surface in advance is hidden. For this reason, by checking the marks 322, 332, 352, it is possible to readily recognize a state of the folding pieces 320, 330 and also it is possible to alleviate a failure of fixing the metal plate member by using a wrong screw hole.

Here, in the above description, a personal computer is described as an example of the information display apparatus explained in the “Disclosure of the Invention.” However, the information display apparatus may be a monitor for computer, a note book type computer, a PDA, a game machine, a television set, a mobile phone and the like as far as a metal plate member is fixed to a display panel.

In addition, a LCD panel is exemplified as the display panel. However, not limited to a LCD panel, whatever kinds of the display panels, a panel of a plasma display, a field emission display, an organic electroluminescence display and the like may be used.

In addition, in the foregoing, an example in which two folding pieces are provided as the plurality folding pieces of the above-described basic mode is explained. However, the above-described basic mode may be one in which three or more folding pieces having through holes communicating screw holes provided in the three or more display panels respectively.

In addition, in the foregoing, an example in which a mark is inscribed when the folding pieces are folded is explained, However, a mark may be marked in advance at a position of a bottom face side of the folding piece which is exposed on a surface when folded.

Further, in the foregoing, display panels of different manufacturers are exemplified. However, the above-described metal plate member may be utilized for LCD panels of different product models from a same manufacture.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A metal plate member, comprising:
a long opening that is formed therein to communicate with a screw hole of each kind of a plurality kinds of panels in each of which the screw hole is formed at a position different from one another on each side face, wherein
the metal plate member is screwed by using the long opening and the screw hole so as to be fixed to each of the plurality kinds of panels, and
the metal plate member further comprises a plurality of folding pieces each of which is formed with a through hole, and is processed to be folded to a overlapping position where the through hole overlaps the long opening, and which correspond to the kinds of panels, the through hole of one folding piece overlaps a portion of the long opening which portion communicates the screw hole formed on the side face of a corresponding kind of panel, the one folding piece blocks a screw hole formed on a side face in each of the other kinds of panels, and one of the plurality of folding pieces is processed to be folded to the overlapping position.

2. The metal plate member according to claim 1, wherein, at a position where one folding piece processed to be folded to the overlapping position, of the plurality of folding pieces, is exposed in a state of being folded, a mark corresponding to the one folding piece is marked.

3. The metal plate member according to claim 1, wherein the long opening is a long opening extending in a thickness direction of the panel, and the through hole of each of the plurality of the folding pieces is a long opening extending in a direction intersecting the direction in which the long opening extends.

4. The metal plate member according to claim 2, wherein the long opening is a long opening extending in a thickness direction of the panel, and the through hole of each of the plurality of the folding pieces is a long opening extending in a direction intersecting the direction in which the long opening extends.

5. The metal plate member according to one of claim 1, wherein the panel is a display panel which includes a display screen to display information, and the metal plate member is fixed to the side face of the panel, and spreads in a rear face side of the display screen.

6. The metal plate member according to one of claim 2, wherein the panel is a display panel which includes a display screen to display information, and the metal plate member is fixed to the side face of the panel, and spreads in a rear face side of the display screen.

7. The metal plate member according to one of claim 3, wherein the panel is a display panel which includes a display screen to display information, and the metal plate member is fixed to the side face of the panel, and spreads in a rear face side of the display screen.

8. The metal plate member according to one of claim 4, wherein the panel is a display panel which includes a display screen to display information, and the metal plate member is fixed to the side face of the panel, and spreads in a rear face side of the display screen.

9. An information display apparatus, comprising:
a first display panel that is formed with a screw hole on a side face, and includes a display screen to display information;
a metal plate member that includes a long opening which is formed therein to communicate with a screw hole of each kind of a plurality kinds of display panels in each of which the screw hole is formed at a position different from one another on each side face, and that is screwed by using the long opening and the screw hole so as to be fixed to each of the plurality kinds of display panels; and
a main unit housing in which the display panel fixed to the metal plate member is housed, wherein
the metal plate member includes a plurality of folding pieces each of which is formed with a through hole, and is processed to be folded to a overlapping position where the through hole overlaps the long opening, and which correspond to the kinds of display panels, the through hole of one folding piece overlaps a portion of the long opening which portion communicates the screw hole formed on the side face of a corresponding kind of display panel, the one folding piece blocks a screw hole formed on a side face in each of the other kinds of display panels, and one folding piece corresponding to the first display panel of the plurality of folding pieces is processed to be folded to the overlapping position so as to be screwed to the first display panel.

10. A panel unit manufacturing method of manufacturing a panel unit, by screwing a first panel on whose side face a screw hole is formed, and a metal plate member in which a long opening which communicates a screw hole of each kind of panels of a plurality kinds of panels whose screw hole positions of screw holes formed on side faces positions are different from each other, by using the long opening and the screw holes, wherein
the metal plate member further comprises a plurality of folding pieces each of which is formed with a through hole, and is processed to be folded to a overlapping position where the through hole overlaps the long opening, and which correspond to the kinds of panels, the through hole of one folding piece overlaps a portion of the long opening which portion communicates the screw hole formed on the side face of a corresponding kind of panel, the one folding piece blocks a screw hole formed on a side face in each of the other kinds of panels, and
the panel unit manufacturing method comprises:
folding-processing of performing folding-processing, at the overlapping position, one of the folding piece corresponding to the first panel of the plurality of folding pieces; and
screwing, by using a screw, to the first panel, the metal plate member in a folded state obtained through the folding-processing.

11. The panel unit manufacturing method according to claim 10, the folding-processing is processing of folding-processing, at the overlapping position, a folding piece corresponding to the first panel of the plurality of folding pieces, and marking a mark according to the folding piece at a position where the folding piece to be folded is in the folded state.
